(19) United States
(12) Patent Application Publication
(10) Pub. No.: US 2025/0355060 A1
(43) Pub. Date: Nov. 20, 2025

(54) SYSTEM AND METHOD FOR INTEGRITY ANALYSIS OF ELECTRIC MEDIUM

(71) Applicant: Daimler Truck North America, LLC, Portland, OR (US)

(72) Inventor: Kurtis Alexander WENDLING, Portland, OR (US)

(21) Appl. No.: 19/213,596

(22) Filed: May 20, 2025

Related U.S. Application Data
(60) Provisional application No. 63/649,587, filed on May 20, 2024.

(51) Int. Cl. G01R 31/58; B60R 16/02; G01K 3/00; G01R 27/08

(52) U.S. Cl. CPC G01R 31/58; B60R 16/0207; G01K 3/005; G01R 27/08

(57) ABSTRACT

Aspects of the present disclosure include a method, a system, and/or a computer readable medium for detecting a degradation by measuring one or more temperatures of the vehicle, transmitting, in response to the one or more temperatures being below a threshold temperature, a first signal to activate a switch to charge or discharge a capacitor of the electrical circuit to a predetermined charge level, transmitting, in response to the capacitor being charged or discharged to a predetermined voltage level, a second signal to close the switch that causes an inrush current to flow through a harness in the electrical circuit, measuring an electrical response associated with the harness based on the inrush current, and determining a presence of a degradation associated with the harness based on the electrical response.

### CROSS REFERENCE TO RELATED APPLICATIONS

The present application claims priority to, and the benefit of, U.S. Provisional Application 63/649,587 filed May 20, 2024 and entitled “SYSTEM AND METHOD FOR INTEGRITY ANALYSIS OF ELECTRIC MEDIUM,” the contents of which are hereby incorporated by reference in their entireties.

### FIELD OF THE INVENTION

The present disclosure relates generally to integrity analysis. More specifically, the present disclosure relates to a system and method for integrity analysis of one or more electric mediums.

### BACKGROUND

A vehicle may include a wire harness that includes a number of wires and/or cables for conducting electricity. The wires and/or cables in a wire harness (also referred to as a harness) may degrade due to various reasons, such as physical damage, oxidation, and/or other causes. The degradations may cause an increase in electrical resistances that may adversely impact the operations of electrical devices connected to the wires and/or cables. As such, it may be important to detect the degradations to timely replace any damaged wires and/or cables. However, it may be difficult to detect the degradations. Therefore, improvements may be desirable.

### SUMMARY

This summary is provided to introduce a selection of concepts in a simplified form that are further described below in the DETAILED DESCRIPTION. This summary is not intended to identify key features of the claimed subject matter, nor is it intended to be used as an aid in determining the scope of the claimed subject matter.

Aspects of the present disclosure include a method, a system, and/or a computer readable medium for detecting a degradation by measuring one or more temperatures of the vehicle, transmitting, in response to the one or more temperatures being below a threshold temperature, a first signal to activate a switch to charge or discharge a capacitor of the electrical circuit to a predetermined charge level, transmitting, in response to the capacitor being charged or discharged to a predetermined voltage level, a second signal to close the switch that causes an inrush current to flow through a harness in the electrical circuit, measuring an electrical response associated with the harness based on the inrush current, and determining a presence of a degradation associated with the harness based on the electrical response.

The methods and systems disclosed herein may be implemented by any means necessary for achieving various aspects, and may be executed in a form of a non-transitory machine-readable medium embodying a set of instructions that, when executed by a machine, causes the machine to perform any of the operations disclosed herein. Other features will be apparent from the accompanying drawings and from the detailed description that follows.

### BRIEF DESCRIPTION OF THE FIGURES

These and other aspects of the present disclosure will now be described in more detail, with reference to the appended drawings showing exemplary aspects, in which:

FIG. 1 is a circuit diagram of an electrical system in a vehicle according to aspects of the present disclosure.

FIG. 2 is a block diagram of an electrical circuit for identifying degradations and an inset graph of current in the electrical circuit over time for identifying degradations according to aspects of the present disclosure.

FIG. 3 is a block diagram of a circuit configured to implement a compensation scheme to account for changes in capacitance during degradation detection and an inset graph of voltage in the circuit over time resulting from the compensation scheme according to aspects of the present disclosure.

FIG. 4 is a block diagram of an example of the controller according to aspects of the present disclosure.

FIGS. 5A and 5B are tables illustrating measurement data and baseline data and FIG. 5C is a timeline illustrating the measurement data M(t₀)-M(tₙ) obtained at different time instances according to aspects of the present disclosure.

FIG. 6 is a flow chart of a method for detecting degradation according to aspects of the present disclosure.

FIGS. 7A-B are flow charts of a method for determining an integrity score according to aspects of the present disclosure.

FIG. 8 is a block diagram of a RLC circuit according to aspects of the present disclosure.

FIG. 9 is a block diagram of various components of an autonomous driving kit of a vehicle according to aspects of the present disclosure.

Other features of the present aspects will be apparent from the accompanying drawings and from the detailed description that follows.

### DETAILED DESCRIPTION

Aspects of the present disclosure include identifying potential degradations in the electrical system of a vehicle. Specifically, aspects of the present disclosure include identifying any degradations in the wire harness of the electrical system. Suitable examples of the wire harness include, but are not limited to, one or more of electrical cables or wires that connect electrical components within the device. In one implementation, for instance, the wire harness may include one or more wires, buses, or cables in a vehicle that connect electrical components like sensors, electronic control units, batteries, and/or actuators.

In an aspect, the present disclosure includes a scheme that utilizes a measurement of current for identifying potential degradations in the electrical system without manually probing nodes within the electrical system.

In some aspects, a degradation in the electrical system may include any degradation associated with an electrical circuit and/or the wire harness associated with the electrical circuit. Suitable examples of an electrical circuit include, but are not limited to, one or more of a resistor, inductor, a capacitor, a power supply, a sensor, an electronic control unit (ECU), an actuator, and/or other components within the electrical system. If a degradation is identified, an aspect of the present disclosure may include taking precautionary, preventive, and/or corrective actions to ensure proper operations of the vehicle.

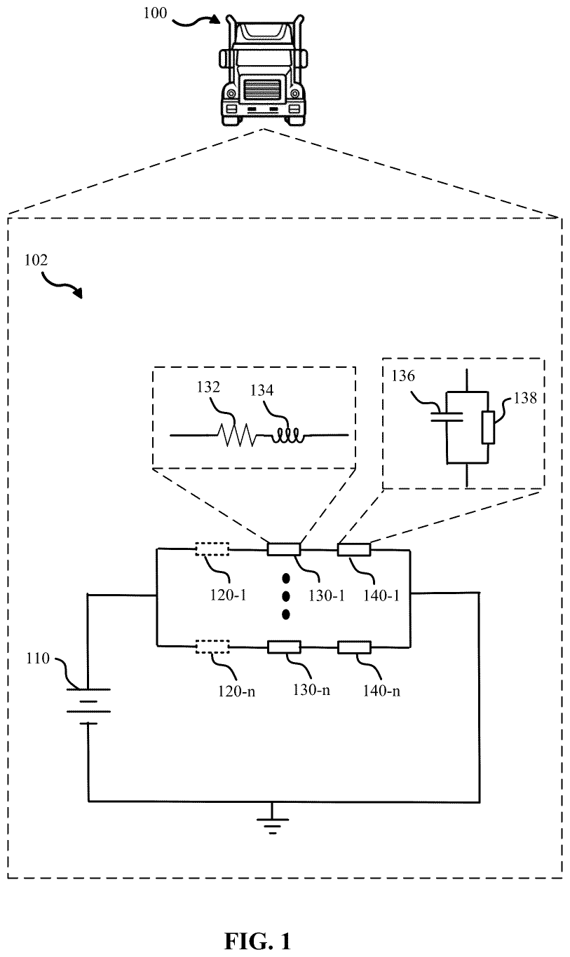

FIG. 1 includes an example of a circuit diagram of an electrical system 102 in a vehicle 100 according to some aspects of the present disclosure. In some aspects, the vehicle 100 utilizes the electrical system 102 for operating various devices. The electrical system 102 may include a power supply 110 configured to provide electrical energy to the components of the electrical system 102. The power supply 110 may be a power source used in a vehicle, such as, for example, a battery, an alternator, a charging port, and/or a power converter. In one example, the supply voltage of the power supply 110 may a direct current (DC) voltage. A voltage level of the supply voltage may be between 5 V to 50 V, or 10 V to 40 V, or other voltage ranges as may be suitable for a given application. In some aspects the supply voltage of the power supply 110 may be 12 V, 24 V, 36 V, or 48 V. Other voltages and/or voltage ranges may also be implemented as may be suitable for a given application, according to various aspects of the present disclosure.

During operation, the power supply 110 may supply electrical energy to each of the plurality of loads 140-1 . . . 140-n via the corresponding harness 130 of the plurality of harnesses 130-1 . . . 130-n and/or the plurality of wire protectors 120-1 . . . 120-n, where n may be any positive integer . . .

In one aspect, the electrical system 102 may optionally include a plurality of wire protectors 120-1 . . . 120-n. The plurality of wire protectors 120-1 . . . 120-n may be configured to disrupt a flow of electrical current from the power supply 110 to remaining portions of the electrical system 102. For example, in one implementation, the plurality of wire protectors 120-1 . . . 120-n may each include a fuse configured to melt when an electrical current threshold is met, thereby breaking the flow of electrical current.

In some aspects of the present disclosure, the electrical system 102 may include a plurality of harnesses 130-1 . . . 130-n. Each of the plurality of harnesses 130-1 . . . 130-n may include one or more wires, cables, cords, leads, traces (e.g., traces on a printed circuit board), and/or other components having one or more strands of a material, e.g., a metal, that conducts electricity. In one aspect, each of the plurality of harnesses 130-1 . . . 130-n may be modeled as a combination of one or more resistors 132 and/or one or more inductors 134.

In an aspects of the present disclosure, the electrical system 102 may include a plurality of loads 140-1 . . . 140-n. Each of the plurality of loads 140-1 . . . 140-n may include one or more capacitors 136 and/or one or more load resistors 138. The plurality of loads 140-1 . . . 140-n may include one or more sensors, electronic control units, lights, heating, ventilation, and air conditioning (HVAC) units, entertainment systems, and/or other components such as any electrically powered component in a vehicle.

In certain aspects of the present disclosure, the plurality of loads 140-1 . . . 140-n may include high integrity loads that are necessary for the vehicle 100 to operate safely during an occurrence of a degradation. In one aspect of the present disclosure, the term high integrity load as used herein refers to high integrity loads compliant with the ISO 26262 standards. In an implementation, the high integrity loads include an automotive safety integrity level D (ASIL-D) or ASIL-B (D) loads providing the required control for the proper maneuvering of the vehicle. In one example, the high integrity loads may include one or more of a brake system, a steering system, a visual sensor system, a virtual driver system, a fuel pump system, and/or other systems that contribute to the proper operation of the vehicle 100.

In some aspects of the present disclosure, the plurality of loads 140-1 . . . 140-n may include high integrity loads that include systems that are not necessary for the vehicle 100 to operate safely during an occurrence of a degradation. In one aspect of the present disclosure, the term non-high integrity loads as used herein refers to quality managed (QM) loads in the vehicle 100. The QM loads may form the least critical workload according to the International Organization for Standardization (ISO) 26262 functional safety standard. QM loads are non-high integrity loads such that the degradation of such loads does not have an adverse effect on the vehicle operation. The QM loads may include, but are not limited to, loads such as audio system, internal lighting, cooling or heating, etc. In an example, the first plurality non-high integrity loads 130-1 may include one or more of a lighting system, an entertainment system, a navigation system, a heating, ventilation, and air conditioning system, and/or other systems or loads that do not interfere with the proper operation of the electrical system 102 and/or vehicle 100.

In an aspect of the present disclosure, the plurality of loads 140-1 . . . 140-n may include one or more electronic control units configured to control one or more components in the vehicle 100.

In one aspect of the present disclosure, the plurality of loads 140-1 . . . 140-n may include a combination of high integrity and non-high integrity loads.

In some instances, degradations in the plurality of harnesses 130-1 . . . 130-n may occur due to corrosion or oxidations to the electrically-conductive material in at least one of the plurality of harnesses 130-1 . . . 130-n, thermal degradations, weather degradations, physical degradations, and/or other mechanisms that may increase the resistances of one or more of the plurality of harnesses 130-1 . . . 130-n (e.g., the one or more resistors 132). However, degradations of the plurality of harnesses 130-1 . . . 130-n may be challenging to detect. For example, the plurality of harnesses 130-1 . . . 130-n may be embedded or otherwise positioned within the vehicle 100 at inaccessible locations, such as at locations within the vehicle 100 that are not exposed or easily reachable by a user. To access the plurality of harnesses 130-1 . . . 130-n, a user, who may also be referred to as a tester, may first remove certain covers that protect the plurality of harnesses 130-1 . . . 130-n. Further, the tester may manually probe various locations throughout the plurality of harnesses 130-1 . . . 130-n to detect the increase in resistance.

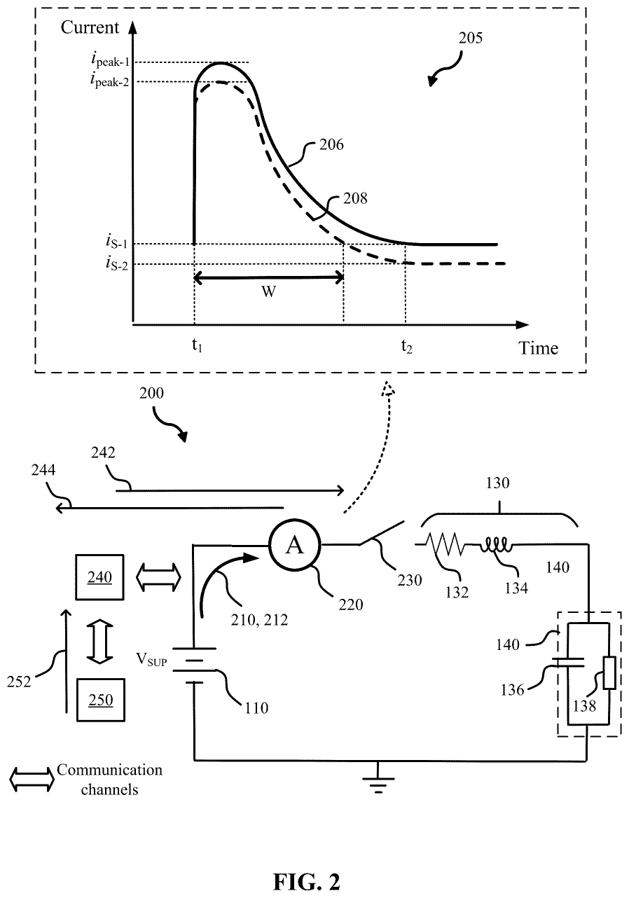

FIG. 2 includes an example of an electrical circuit 200 for identifying degradations and a current graph 205 for identifying degradations according to various aspects of the present disclosure. Referring to FIGS. 1 and 2, in some aspects of the present disclosure, the electrical circuit 200 may include an ammeter 220 disposed between the power supply 110 and a load 140 of the plurality of loads 140-1 . . . 140-n. The electrical circuit 200 may include a switch 230 configured to form an open or a short connection between the power supply 110 and the load 140. Examples of the switch 230 may include a metal-oxide-semiconductor field effect transistor (MOSFET), a bipolar junction transistor (BJT), an insulated gate bipolar transistor (IGBT), a relay, and/or other suitable devices configured to form an open connection or a short in the circuit. The electrical circuit 200 may include a controller 240 configured to determine degradation of a harness 130 of the plurality harnesses 130-1 . . . 130-n as described below. The electrical circuit 200 may include one or more temperature sensors 250 configured to measure one or more temperatures within the vehicle 100. As used herein, a “sensor” is a device that detects and measures physical properties from the surrounding environment and converts this information into electrical or digital signals. Sensors may be made of electronic, mechanical, chemical, or other engineering components. In an aspect, sensors may be removably or fixedly installed within the vehicle 100 and/or may be disposed in various arrangements.

In some aspects, the controller 240 may be configured to communicate with various components within the electrical circuit 200 via one or more communication channels. For example, the controller 240 may be configured to transmit control signals to and/or receive data signals from one or more of the ammeter 220, the switch 230, and/or the one or more temperature sensors 250.

The controller 240 may first identify a baseline parameter (e.g., such as the initial resistance of the harness 130) prior to degradation. For example, the controller 240 may identify the baseline parameter after the harness 130 is installed into the vehicle 100 (and before any or extensive driving operations). Additionally or alternatively, the controller 240 may perform the scheme at or under a certain threshold temperature. As such, the controller 240 may receive one or more sensor signals 252 from the one or more temperature sensors 250. The one or more sensor signals 252 may indicate the temperatures of the vehicle 100. The controller 240 may begin and/or perform the scheme described herein after the temperature of the vehicle 100 (as indicated by the one or more sensor signals 252) falls below the threshold temperature. Examples of the threshold temperature may be in a range of approximately −40° C. to 80° C., −20° C. to 70° C., −10° C. to 60° C., or other ranges. Other suitable threshold temperature and/or threshold temperature ranges may be used. In some aspects, the scheme according to an aspect of the present disclosure may be implemented after the temperature of the vehicle 100 falls below the threshold temperature or moves within the threshold temperature range. In one aspect, the scheme may be implemented after the temperature of the vehicle 100 falls below the threshold temperature or moves within the threshold temperature range for a predetermined amount of time (e.g., 10 minutes, 20 minutes, 30 minutes, 1 hour, 2 hours, 4 hours, 6 hours, etc.).

In certain aspects, in response to the temperature of the vehicle 100 falling below the threshold temperature, the controller 240 may transmit a signal 242 to open the switch 230 to stop the flow of electrical energy from the power supply 110 to the load 140. As such, the charges on the capacitor 136 may discharge completely, or to a certain charge level (as further described below). In one aspect, the controller 240 may wait a predetermined amount of time for the capacitor 136 to discharge.

In an aspect, the controller 240 may close the switch 230 to provide an electrical connection between the power supply 110 and the harness 130 and/or the load 140. As such, an initial inrush current 210 may flow from the power supply 110, through the harness 130, through the load 140, and back to the power supply 110 via a loop. The ammeter 220 may measure an initial magnitude 206 of the initial inrush current 210. In some aspects, the initial magnitude 206 of the initial inrush current 210 may vary over time as shown in the current diagram 205. The magnitude 206 of the initial inrush current 210 (prior to degradation) may peak at the value of an initial peak current value iₚₑₐₖ₋₁ and eventually “settle” to an initial steady state current value is −1. The ammeter 220 may transmit the measured initial magnitude 206 to the controller 240 via a signal 244.

In some aspects, the initial magnitude 206 of the initial inrush current 210 may be dependent on one or more factors. For example, the initial magnitude 206 of the initial inrush current 210 may be dependent on the resistances of the one or more resistors 132, the inductances of the one or more inductors 134, and/or the capacitances of the one or more capacitors 136. In some aspects, the initial magnitude 206 may be dependent on the load 140. However, the load resistor 138 of the load 140 may be behave like an open circuit at a pulse phase W of the initial inrush current 210 (e.g., prior to the initial inrush current 210 settling to the initial stead state current value is −1). Specifically, the load resistor 138 of the load 140 may be drawing significantly less current than the initial inrush current 210 (e.g., less than 10 times, less than 100 times, etc.). For example, the load resistor 138 may have a significantly higher impedance than the impedance of the harness 130. Here, the pulse phase W may last less than 20 milliseconds (ms), 10 ms, 5 ms, 2 ms, or less.

In one aspect of the present disclosure, the controller 240 may receive the initial magnitude 206 of the initial inrush current 210. The controller 240 may compute the initial resistance Rr of the harness 130 based on the initial peak current value iₚₑₐₖ₋₁ and the supply voltage V_{SUP} of the power supply 110. For example, the controller 240 may divide the supply voltage V_{SUP} by the initial peak current value iₚₑₐₖ₋₁ to obtain the initial resistance R_{I} of the harness 130. Here, the initial resistance R_{I} of the harness 130 may be the “inherent” resistance of the harness 130 without any degradation. In one aspect, the controller 240 may use the initial resistance R_{I} of the harness 130 as the baseline parameter. Other baseline parameters may also be used according to various aspects of the present disclosure. For example, the initial resistance R_{I}, the initial peak current value iₚₑₐₖ₋₁ and/or the initial steady state current value is-1 may also be used, alone or in any combination, as the baseline parameter.

In some aspects of the present disclosure, after one or more time periods of operation of the harness 130 in the vehicle 100, the controller 240 may subsequently determine any degradation of the harness 130. In one aspect, the controller 240 may repeat the measurement above after a certain period of time (e.g., 1 week, 2 weeks, 1 month, 2 months, 3 months, 5 months, 6 months, or other periods of time). After identifying the baseline parameter as described above, the controller 240 may identify a presence of degradation as follows. The controller 240 may receive one or more sensor signals 252 from the one or more temperature sensors 250. The one or more sensor signals 252 may indicate the temperatures of the vehicle 100. The controller 240 may begin and/or perform the scheme described herein after the temperature of the vehicle 100 (as indicated by the one or more sensor signals 252) falls below the threshold temperature.

In response to the temperature of the vehicle 100 falling below the threshold temperature, the controller 240 may transmit the signal 242 to open the switch 230 to stop the flow of electrical energy from the power supply 110 to the load 140. As such, the charges on the capacitor 136 may discharge completely, or to a certain charge level (as further described below). In one aspect, the controller 240 may wait a predetermined amount of time for the capacitor 136 to discharge.

Then, the controller 240 may close the switch 230 to provide an electrical connection between the power supply 110 and the harness 130 and/or the load 140. As such, a subsequent inrush current 212 may flow from the power supply 110, through the harness 130, through the load 140, and back to the power supply 110 via a loop. The ammeter 220 may measure a magnitude 208 of the subsequent inrush current 212 (e.g., which may be after degradation). In some aspects, the magnitude 208 of the subsequent inrush current 212 may vary over time as shown in the current graph 205. The magnitude 208 of the subsequent inrush current 212 may peak at the value of a peak current value iₚₑₐₖ₋₂ and eventually “settle” to a steady state current value is −2. The ammeter 220 may transmit the measured magnitude 208 to the controller 240 via the signal 244.

In some aspects, the magnitude 208 of the subsequent inrush current 212 may be dependent on one or more factors. For example, the magnitude 208 of the inrush current 212 may be dependent on the resistances of the one or more resistors 132, the inductances of the one or more inductors 134, and/or the capacitances of the one or more capacitors 136. In some aspects, the magnitude 208 may be dependent on the load 140. Here, a degradation of the harness 130 may contribute to an increase in the resistance of the harness 130. However, the degradation of the harness 130 may not change the inductances of the one or more inductors 134 (e.g., wire/cable lengths of the harness 130 and the vehicle routing may be unchanged). Further, the change in capacitances of the one or more capacitors 136 may be zero, or accounted for as described in the scheme below. As such, any change between the initial inrush current 210 and the subsequent inrush current 212 may be due to the degradation of the harness 130, such as an increase in the resistance of the harness 130.

In one aspect of the present disclosure, the controller 240 may receive the magnitude 208 of the subsequent inrush current 212. The controller 240 may compute the resistance R of the harness 130 based on the peak current value iₚₑₐₖ₋₂ and the supply voltage V_{SUP} of the power supply 110. For example, the controller 240 may divide the supply voltage V_{SUP} by the peak current value iₚₑₐₖ₋₂ to obtain the resistance R of the harness 130. In one aspect, the controller 240 may calculate a change in resistance ΔR of the harness 130 based on resistance R and the initial resistance R_{I}. The change in resistance ΔR of the harness 130 may indicate the level of degradation of the harness. As discussed above, other parameters may also be used to assess the degradation of the harness as described above.

In some aspects, the process above may be repeated periodically and/or aperiodically to track the degradation of the harness.

In one aspect of the present disclosure, the controller 240 may execute the scheme above (for the baseline parameter and/or any of the follow-up measurements) using the electrical energy from the battery (not shown) of the vehicle 100 for the inrush currents. Specifically, the controller 240 may execute the scheme above when the state of the charge for the battery is at a predetermined level. For example, the controller 240 may execute the scheme when the battery is fully charged. By charging the battery to a predetermined level prior to executing the scheme, the controller 240 may reduce, ignore, and/or eliminate the effect of the battery on the measured current. Other levels are also possible.

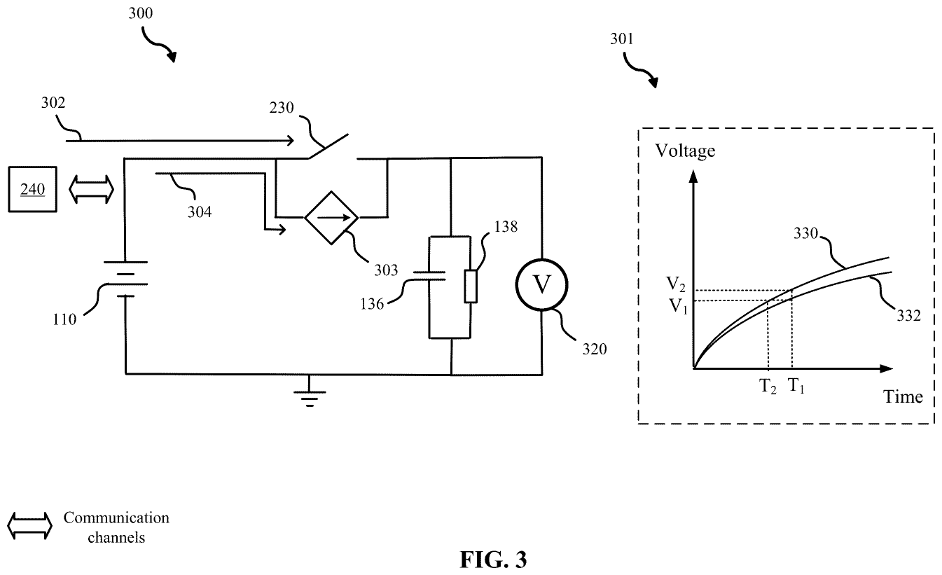

FIG. 3 includes an example of a circuit 300 configured to implement a compensation scheme to account for changes in capacitance during degradation detection in accordance with a voltage graph 301 showing the compensation scheme according to various aspects of the present disclosure. In this scheme, circuit 300 is a modified version of circuit 200 of FIG. 2. Specifically, the scheme may include identifying any degradation in the capacitance (i.e., decrease in capacitance) of the one or more capacitors 136. As such, the degradation in the harness 130 (e.g., change in resistance ΔR of the harness 130) may be accurately computed as described below.

In some aspects, the scheme may include providing a charge pump 303 between the power supply 110 and the load 140. Certain components (e.g., the one or more resistors 132) are omitted for clarify. The scheme may be applied before any degradation in the capacitance of the one or more capacitors 136 and after the degradation in the capacitance of the one or more capacitors 136.

During operation, the controller 240 may transmit a signal 302 to a switch 230 to open the switch 230. Next, the controller 240 may transmit a signal 304 to the charge pump 303 to supply a predetermined number of charges to the one or more capacitors 136. The voltmeter 320 may measure the voltage across the one or more capacitors 136. The measured voltages during the charging of the one or more capacitors 136 may be transmitted to the controller 240.

Here, a first voltage curve 330 may show the measured voltages of the one or more capacitors 136 being charged by the charge pump 303. A second voltage curve 332 may show the measured voltages of the one or more capacitors 136 being charged by the charge pump 303 after degradation. For example, after time T₁ the voltage across the one or more capacitors 136 may be V₁. If any degradation occurs to the one or more capacitors 136 (i.e., reduction in the capacitance), and assuming the charge pump 303 maintains its charge supplying rate, the voltage across the one or more capacitors 136 may be V₂ (which is larger than V₁) after time T₁ of charging. Alternatively, it may take the charge pump 303 up to time T₂ (which is shorter than T₁) to charge the one or more capacitors 136 to the same voltage V₁. Based on the difference in voltage and/or charging time, the controller 240 may determine the degradation in the capacitance of the one or more capacitors 136.

In a first example, the controller 240 may calculate the change in capacitance as a function of the change in voltage, for example, C₁V₁=C₂V₂=Q. Q may the total number of charges supplied by the charge pump 303, which may be unchanged before and after degradation (constant current over the same amount of time, such as time T₁). C₁ may be the capacitance of the one or more capacitors 136 before degradation and C₂ may be the capacitance of the one or more capacitors 136 after degradation. As such, C₂=C₁ (V₁/V₂). Since V₁ is less than V₂ (i.e., the same amount of charge causes a higher voltage across the one or more capacitors 136 due the decrease in capacitance), C₂ is lower than C₁.

In a second example, the controller 240 may calculate the change in capacitance as a function of the change in charges applied, for example, V₁=Q₁/C₁=Q₂/C₂. Here, the charges applied Q₁ and Q₂ are the numbers of charges supplied by the charge pump after T₁ and T₂, respectively. Assuming the same current, the equation above may be rewritten as V₁=T₁/C₁=T₂/C₂, or alternatively, C₂=C₁ (T₂/T₁). Since T₂ is shorter than T₁ (i.e., less charges are needed to induce the same voltage the one or more capacitors 136 due to the decrease in capacitance), C₂ is lower than C₁. Other methods of calculating the decrease in capacitance may also be used according to various aspects of the present disclosure.

Referring to FIGS. 1-3, the change in capacitance determined based on the scheme described above may be incorporated into the determination for the degradation of the harness 130. For example, a portion of the changes in the peak current value iₚₑₐₖ₋₂ may be caused by the change in the capacitance. As such, the controller 240 may determine the resistance R due to degradation by dividing V_{SUP} by the sum of the peak current value iₚₑₐₖ₋₂ and a correction factor. Here, the correction factor may be the contribution to the increase or decrease in the peak current value caused by the increase or decrease in capacitance.

In the electrical circuit 200 (and/or 300), a single harness and a single load is illustrated. However, the scheme described herein may be used to assess the degradation of one or more harnesses (individually or together) according to various aspects of the present disclosure.

In some aspects of the present disclosure, the controller 240 may determine a degradation as an increase in the resistance of the harness 130 above a certain threshold percentage. For example, the controller 240 may determine a 1%, 2%, 5%, 10% or other percentage of increase as the degradation. Consequently, the controller 240 may take one or more precautionary, preventive, and/or corrective actions to ensure proper operations of the vehicle.

In a first example, the controller 240 may detect a degradation of the harness 130 for an autonomous driving kit (ADK, e.g., an example of one of the loads as described below) of the vehicle 100 being above a threshold percentage. Due to the increase in the resistance of the harness 130 for the autonomous driving kit, less power (e.g., less voltage) may be delivered to a steering system of the ADK due to the increase in voltage drop across the harness 130. As such, the controller 240 may transmit one or more signals to the ADK to trigger the ADK to restrict a maximum rotational acceleration and/or rate of the steering system to a desired level (as long as within a minimum level of the ADK).

In a second example, the controller 240 may detect a degradation of the harness 130 for one or more visual sensors for the ADK. As such, the controller 240 may transmit one or more signals to the ADK to check for perception availability due to the degradation of the sensor performance (associated with the lower power supplied to the sensors caused by the increase in harness resistance). The ADK may continue normal operation until further sensor degradation beyond a predetermined threshold, and/or other suitable actions.

In a third example, the controller 240 may detect a degradation of the harness 130 for a braking system of the ADK. As such, the controller 240 may transmit one or more signals to the ADK to communicate a potential reduction in a minimal risk maneuver (MRM) capability of the ADK. In response, the ADK may lower the operational speed of the vehicle 100, initiate brake earlier than expected, or take other actions. Other precautionary, preventive, and/or corrective actions may also be taken by the controller 240 according to various aspects of the present disclosure.

In one aspect of the present disclosure, the schemes described above may be executed on devices other than vehicle harnesses. For example, the scheme described above may be executed on machinery, aircrafts, trains, ships, and/or other devices.

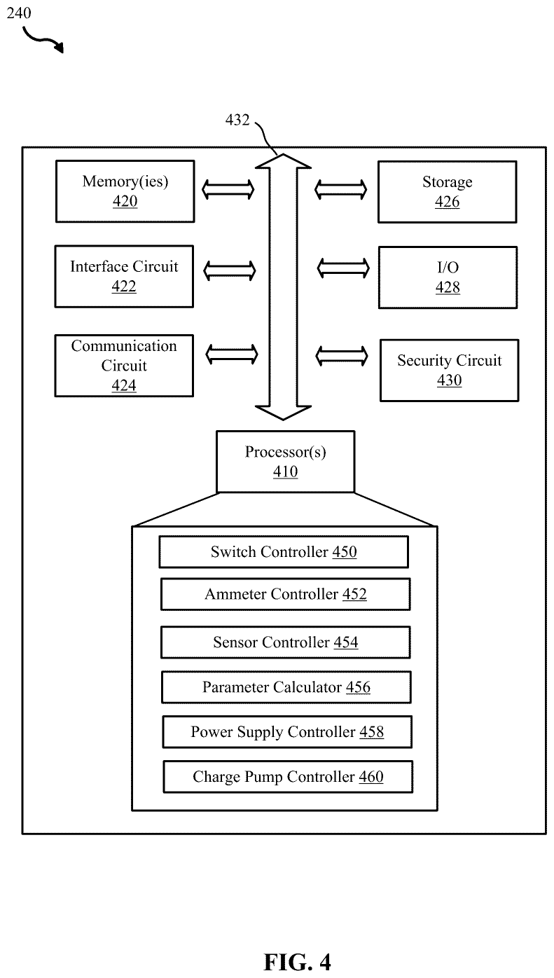

FIG. 4 is a block diagram illustrating an example of the controller 240 according to various aspects of the present disclosure. The controller 240 may be in a single package or as a chip set assembly with multiple components. The controller 240 may be implemented as a single integrated circuit device, or a number of distributed circuit devices. In one aspect, the controller 240 may include one or more processors 410 configured to execute instructions stored in one or more memories 420. The one or more memories 420 may include computer executable instructions that implement various functions of the current disclosure.

The term “processor” as used herein can refer to any computing processing unit and/or device comprising, but not limited to, single-core processors; single-processors with software multi-thread execution capability; multi-core processors; multi-core processors with software multi-thread execution capability; multi-core processors with hardware multi-thread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular based transistors, switches and/or gates, in order to optimize space usage and/or to enhance performance of related equipment. A combination of computing processing units can implement a processor.

Herein, terms such as “store,” “storage,” “data store,” data storage,” “database,” and any other information storage component relevant to operation and functionality of a component refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, and/or nonvolatile random access memory (RAM) (e.g., ferroelectric RAM (FeRAM). Volatile memory can include RAM, which can function as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synch link DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein include, without being limited to including, these and/or any other suitable types of memory.

Computer-executable instructions comprise, for example, instructions and data which cause a general purpose computer, special purpose computer, or special purpose processing device to perform a certain function or group of functions. The computer-executable instructions may be, for example, binary, intermediate format instructions such as assembly language, or even source code. Although the subject matter herein described is in a language specific to structural features and/or methodological acts, the described features or acts described do not limit the subject matter defined in the claims.

The controller 240 may include an interface circuit 422 configured to provide a hardware interface with external devices. The controller 240 may include a communication circuit 424 configured to communicate via wired or wireless communication channels. The controller 240 may include a storage 426 configured to store digital information. The controller 240 may include an input/output (I/O) interface device 428 configured to receive input signals and/or transmit output signals. The controller 240 may include a security circuit 430 configured to authenticate an identity, authenticate a token, manage security keys, encryption keys, and/or decryption keys, encrypt data, and/or decrypt data according to aspects of the present disclosure.

In one aspect, the security circuit 430 may receive a security token (not shown) from an external device. The security circuit 430 may determine whether the external device is a trusted device by authenticating the security token. If authenticated, the security circuit 430 may grant the external device one or more of read privilege (the external device is able to read data in the storage 426), write privilege (the external device is able to modify data in the storage 426 and/or update firmware in the one or more memories 420), or both. The controller 240 may include a bus 432 configured to provide connections among the subcomponents of the controller 240.

In one aspect of the present disclosure, the one or more processors 410 may execute instructions stored in the one or more memories 420 to implement a switch controller 450. The switch controller 450 may be configured to control one or more switches as described above. For example, the switch controller 450 may be configured to transmit a signal to the ECU of a switch, and/or provide a voltage to the gate/base of the switch to change the state of the switch.

In some aspects of the present disclosure, the one or more processors 410 may execute instructions stored in the one or more memories 420 to implement an ammeter controller 452. The ammeter controller 452 may be configured to control the operations of the ammeter 220, including but not limited to performing and/or receiving current measurements.

In some aspects of the present disclosure, the one or more processors 410 may execute instructions stored in the one or more memories 420 to implement a sensor controller 454. The sensor controller 454 may be configured to control the operations of the one or more temperature sensors 250, including but not limited to performing and/or receiving temperature measurements.

In some aspects of the present disclosure, the one or more processors 410 may execute instructions stored in the one or more memories 420 to implement a parameter calculator 456 configured to calculate the resistance of the harness 130 and/or capacitance of the one or more capacitors 136 as described above.

In some aspects of the present disclosure, the one or more processors 410 may execute instructions stored in the one or more memories 420 to implement a power supply controller 458. The power supply controller 458 may be configured to control the voltage and/or current output of the power supply 110.

In some aspects of the present disclosure, the one or more processors 410 may execute instructions stored in the one or more memories 420 to implement a charge pump controller 460. The charge pump controller 460 may be configured to control the voltage and/or current output of the charge pump 303.

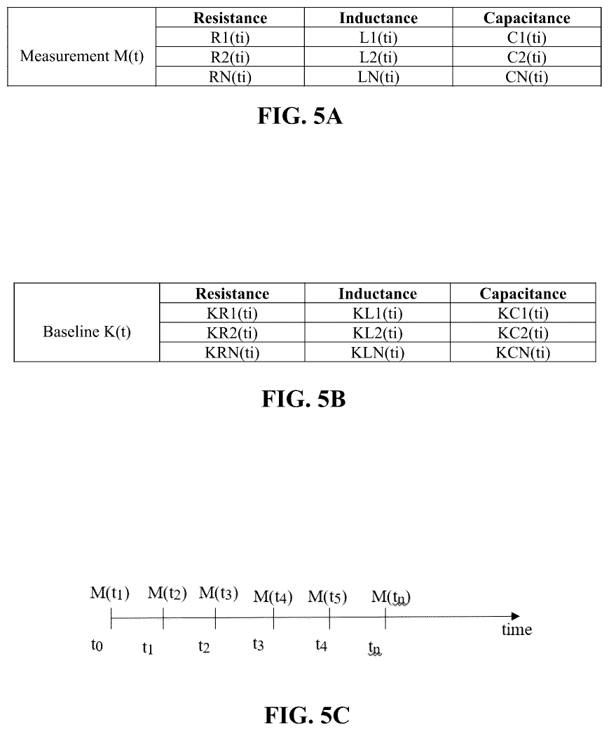

FIG. 5A is a table illustrating measurement data M(tᵢ) that includes a plurality of measurement values R₁(tᵢ), L₁(tᵢ), . . . . C_{N}(tᵢ), wherein these measurement values represent a resistance, an inductance, and a capacitance of each of a plurality of wires. R₁ (tᵢ), for example, is a resistance measurement value associated with a first wire; L₂(tᵢ), for example, is an inductance measurement value associated with a second wire; and C_{N}(tᵢ), for example, is a capacitance measurement value associated with an N^{th} wire. FIG. 5B is a table illustrating baseline data K(tᵢ) that may be compared with the measurement data illustrated in FIG. 5A, wherein the baseline data K(tᵢ) includes a plurality of baseline values, wherein each of these baseline values represents a resistance threshold, an inductance threshold, and a capacitance threshold of each of the plurality of wires.

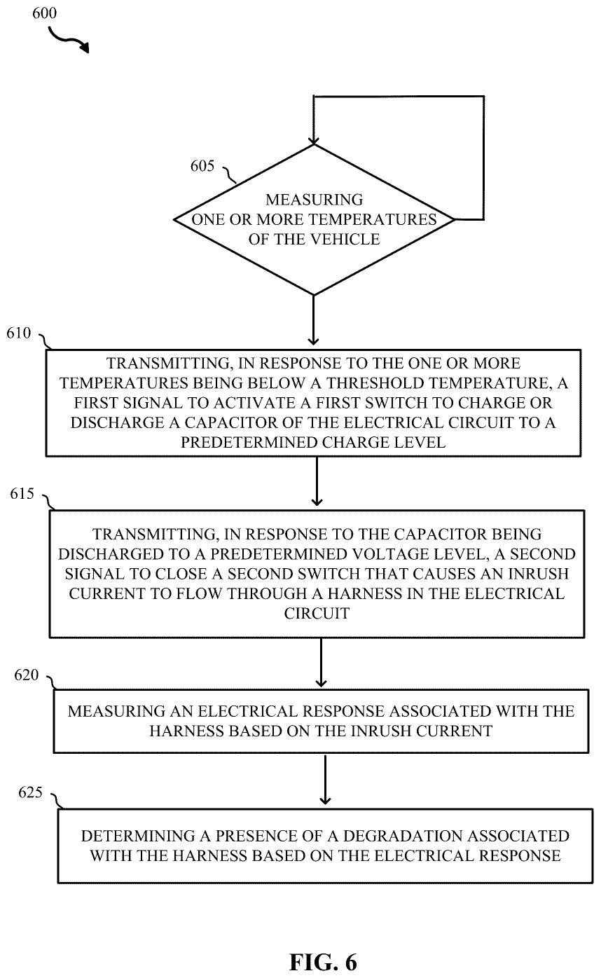

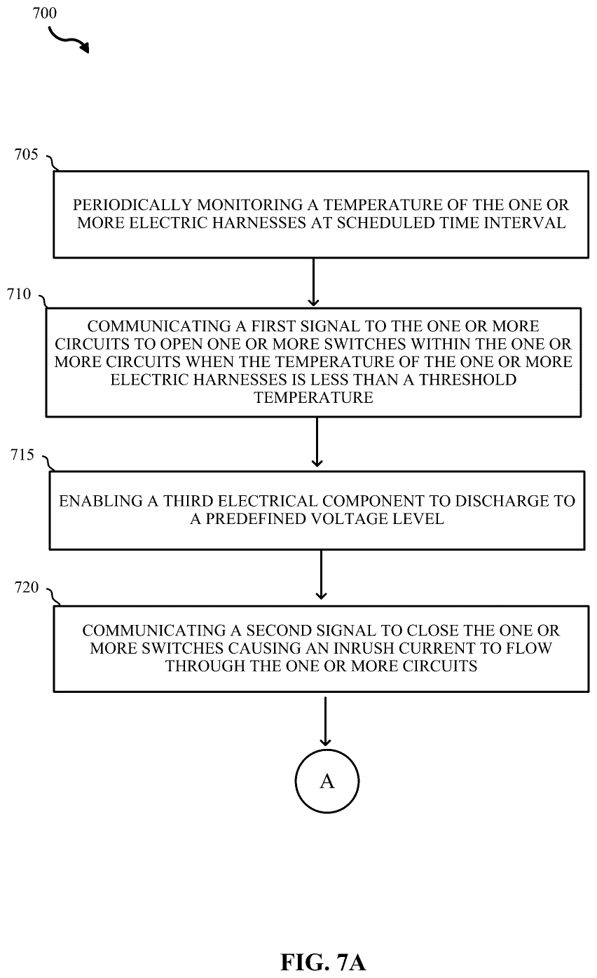

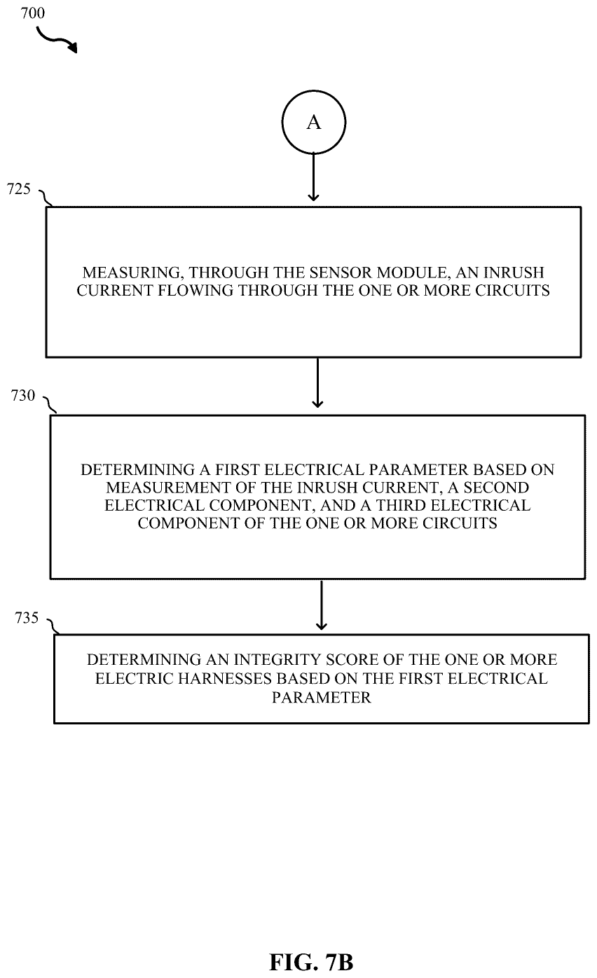

In some aspect, the scheme, such as the methods described below in FIGS. 6 and 7, may use five variables such as resistance, inductance, capacitance, temperature, and voltage f (R, L, C, T, V)=I. The temperature and voltage may be unchanged for determining the resistance. The temperature may be kept below a threshold level by keeping the vehicle 100 rest for, e.g., one to four or more hours. The state-of-charge (V) of the power supply or battery pack may be above the threshold state-of-charge. The threshold state-of-charge may be achieved by connecting the vehicle 100 to a shore charger to increase the state of charge to a predetermined state of charge prior to executing the scheme. The inductance and capacitance may be fixed to determine resistance.

According to one example, comparing the measurement data M(tᵢ) with the baseline data K(tᵢ) includes comparing each measurement value included in the measurement data M(tᵢ) with a respective one of the baseline values in the baseline data K(tᵢ). A wire may be degraded when at least one of the measurement values included in the measurement data M(tᵢ) and associated with the wire does not meet a predefined criteria with regard to the associated baseline value. A baseline value associated with a measurement value may be one of the baseline values that is associated with the same wire and the same electrical parameter as the measurement value. A baseline value associated with the resistance measurement value R₁ (tᵢ) of the first wire, for example, is resistance threshold KR₁(tᵢ) of the first wire, and so on.

In some aspects, a measurement value that does not meet a predefined criteria relative to the respective baseline value may include that the measurement value is higher than the baseline value or is lower than the baseline value. According to one example, the at least one measurement value represents a resistance of a wire and the predefined criteria is that the measurement value is below the baseline value. In this case, the measurement value does not meet the criteria, that is the wire fails the integrity check, when the measurement value is higher than the baseline value.

In certain aspects, the baseline data K(tᵢ) may be obtained in various ways, wherein some methods for obtaining the comparative data are explained in the following example. The methods relate to obtaining one comparative value KV(tᵢ), which is referred to as first baseline value. The first baseline value represents one electrical parameter of one wire, wherein this electrical parameter is referred to as first parameter and the wire is referred to as first wire in the following example. The different baseline values represented by the baseline data may be obtained by using the same method or by using different methods. The measurement value with which the first baseline value is compared is referred to as a first measurement value in the following example.

According to one example, the first comparative value KV(tᵢ) is dependent on at least one earlier measurement value obtained by measuring the first electrical parameter of the first wire after manufacturing the first wire and before the time instance at which the first measurement value is obtained. The at least one earlier measurement value may include an initial measurement value and/or one or more intermediate measurement values.

The initial measurement value is obtained by measuring the first electrical parameter before a first operation of the vehicle 100, wherein the initial measurement value may be obtained before installing the first wire in the vehicle 100 or after installing the first wire in the vehicle 100. In each case, the initial measurement value may be obtained before a first operation of the vehicle 100.

The first baseline value KV(tᵢ) may be dependent only on at least one earlier measurement value. In this case, the first baseline value KV(tᵢ) may be obtained by multiplying one earlier measurement value with a predefined factor or by multiplying a weighted sum of several earlier measurement values with a predefined factor.

FIG. 5C is a timeline illustrating the measurement data M(t₀)-M(tₙ), according to one or more aspects. The measurement data M(t₀)-M(tₙ) are regularly obtained, that is, for example, every week, every month, every year, or the like. In FIG. 5C, the measurement data M(t₀)-M(tₙ) represents measurement data that has been obtained at different time instances t₀, t₁, . . . , tₙ.

According to another example, the controller 240 (FIG. 2) is configured to monitor operating conditions of the wire and to initiate obtaining the measurement data M(tᵢ) whenever a certain operating condition has been detected. In an aspect, the controller 240 is configured to monitor the temperature of the system (which includes the temperature of the electric medium and the entity as well as the ambient temperature). For example, the controller 240 is configured to initiate obtaining the measurement data M(tᵢ) when the temperature of the system is below a threshold temperature.

In another aspect, the controller 240 is configured to track the time that has passed since a last check. For example, the controller 240 is configured to initiate obtaining the measurement data M(tᵢ) when the time has passed a last check is above a threshold time period. In another aspect, the controller 240 is configured to track the rest period of the vehicle 100. For example, the controller 240 is configured to initiate obtaining the measurement data M(tᵢ) when the rest period has crossed above a threshold time period. Once the rest period has crossed above the threshold time period, the temperature of the vehicle 100 is below a threshold temperature.

FIG. 6 is a flow chart of a method 600 for detecting degradation in a harness according to aspects of the present disclosure. The method 600 may be performed by the controller 240, one or more components of the controller 240, the one or more temperature sensors 250, the switch 230, the charge pump 303, and/or the ammeter 220.

At 605, the method 600 may measure one or more temperatures of the vehicle. For example, the controller 240, the one or more processors 410, the one or more memories 420, and/or the one or more temperature sensors 250 may be configured to, and/or provide means for, measuring one or more temperatures of the vehicle 100. If the one or more temperatures of the vehicle arrives at, or beyond, the threshold temperature, the method 600 may proceed to 610. If the one or more temperatures of the vehicle does not arrive at the threshold temperature, the method 600 may continue to measure the one or more temperatures of the vehicle 100.

At 610, the method 600 may transmit, in response to the one or more temperatures being below a threshold temperature, a first signal to activate a switch to charge or discharge a capacitor of the electrical circuit to a predetermined charge level. For example, the controller 240, the switch controller 450, the one or more processors 410, and/or the one or more memories 420 may be configured to, and/or provide means for, transmitting, in response to the one or more temperatures being below a threshold temperature, the signals 242, 302 to activate the switch 230 to charge or discharge the one or more capacitors 136 of the electrical circuit 200 to a predetermined charge level.

At 615, the method 600 may transmit, in response to the capacitor being charged or discharged to a predetermined voltage level, a second signal to close the switch that causes an inrush current to flow through a harness in the electrical circuit. For example, the controller 240, the switch controller 450, the switch 230, the charge pump 303, the one or more processors 410, and/or the one or more memories 420 may be configured to, and/or provide means for, transmitting, in response to the one or more capacitors 136 being charged or discharged to a predetermined voltage level, the signal 242 to close the switch 230 that causes the inrush current 212 to flow through the harness 130 in the electrical circuit 200.

At 620, the method 600 may measure an electrical response associated with the harness based on the inrush current. For example, the controller 240, the ammeter controller 452, the parameter calculator 456, the one or more processors 410, and/or the one or more memories 420 may be configured to, and/or provide means for, measuring the resistance R of the harness 130 based on the inrush current 212.

At 625, the method 600 may determine a presence of a degradation associated with the harness based on the electrical response. For example, the controller 240, the ammeter controller 452, the parameter calculator 456, the one or more processors 410, and/or the one or more memories 420 may be configured to, and/or provide means for, determining a presence of a degradation associated with the harness 130 based on the resistance R.

Aspects of the present disclosure include a method for detecting a degradation by measuring one or more temperatures of the vehicle, transmitting, in response to the one or more temperatures being below a threshold temperature, a first signal to activate a switch to charge or discharge a capacitor of the electrical circuit to a predetermined charge level, transmitting, in response to the capacitor being charged or discharged to a predetermined voltage level, a second signal to close the switch that causes an inrush current to flow through a harness in the electrical circuit, measuring an electrical response associated with the harness based on the inrush current, and determining a presence of a degradation associated with the harness based on the electrical response.

Aspects of the present disclosure include the method above, wherein measuring the electrical response comprises measuring a current through the harness and determining a resistance of the harness based a voltage used to apply the inrush current and the measured current.

Aspects of the present disclosure include any of the methods above, further comprising, prior to measuring the electrical response associated with the harness transmitting a first initial signal to open the switch to discharge initial charges in the capacitor, transmitting, in response to the capacitor being charged or discharged to the predetermined voltage level, a second initial signal to close the switch that causes an initial inrush current to flow toward the harness, measuring an initial electrical response associated with the harness based on the initial inrush current, and determining a baseline parameter associated with the harness based on the initial electrical response.

Aspects of the present disclosure include any of the methods above, wherein measuring the initial electrical response comprises measuring an initial current through the harness and determining an initial resistance of the harness based on an initial voltage applied to apply the initial inrush current and the initial current.

Aspects of the present disclosure include any of the methods above, wherein determining the baseline parameter comprises identifying the initial resistance of the harness as the baseline parameter.

Aspects of the present disclosure include any of the methods above, wherein determining the degradation associated with the harness comprises determining a change in resistance based on a difference in the resistance and the initial resistance and determining the degradation based on the change in resistance.

Aspects of the present disclosure include any of the methods above, further comprising comparing the degradation to a threshold degradation, determining, in response to comparing the degradation to the threshold degradation, the degradation being above the threshold degradation, performing one or more of transmitting, to a system of the vehicle, one or more signals to reduce an ability associated with the system, the system comprising the harness, transmitting, to a system of the vehicle, one or more signals to monitor an ability associated with the system, the system comprising the harness, or transmitting, to a system of the vehicle, one or more signals to terminate an ability associated with the system, the system comprising the harness.

Aspects of the present disclosure include any of the methods above, further comprising, periodically transmitting a first plurality of signals to open the switch to discharge the capacitor of the electrical circuit, transmitting, in response to the capacitor being charged or discharged to the predetermined voltage level, a second plurality of signals to close the switch that causes a plurality of inrush currents to flow through the harness in the electrical circuit, measuring a plurality of electrical responses associated with the harness each based on the plurality of inrush currents, and determining one or more degradations associated with the harness based on the plurality of electrical responses. For example, the method 600 may be repeated periodically (e.g., every day, every week, every month, every 3 months, or other periodicities) or aperiodically.

FIGS. 7A-B are flow charts illustrating a method 700 for determining degradation according to one or more aspects. The method comprises: monitoring periodically, through one or more sensor modules, a temperature of one or more components, such as a harness, at a scheduled time intervals (at step 705); communicating a first signal to one or more circuits to open one or more switches within the one or more circuits when the temperature of the one or more harnesses is less than a threshold temperature (at step 710); enabling a third electrical component to discharge to a predefined voltage level (at step 715); communicating a second signal to the one or more circuits to close the one or more switches causing an inrush current to flow through the one or more circuits (at step 720); measuring, through the one or more sensor modules, the inrush current flowing through the one or more circuits (at step 725); determine a first electrical parameter based on the measurement of the inrush current, a second electrical component, and the third electrical component of the one or more circuits (at step 730); and determine an integrity score of the one or more harnesses based on the first electrical parameter (at step 735).

In an aspect, a system is described. The system comprises: one or more sensor modules; one or more electric harnesses; one or more circuits; and a processor. The processor storing instructions in non-transitory memory that, when executed, causes the processor to: periodically monitor, through the one or more sensor modules, a temperature of the one or more electric harnesses at a scheduled time intervals; communicate a first signal to the one or more circuits to open one or more switches within the one or more circuits when the temperature of the one or more electric harnesses is less than a threshold temperature; enable a third electrical component to discharge to a predefined voltage level; communicate a second signal to the one or more circuits to close the one or more switches causing an inrush current to flow through the one or more circuits; measure, through the one or more sensor modules, the inrush current flowing through the one or more circuits; determine a first electrical parameter based on measurement of the inrush current, a second electrical component, and the third electrical component of the one or more circuits; and determine an integrity score of the one or more electric harnesses based on the first electrical parameter.

In one aspect, a circuit of the one or more circuits comprises a resistance, inductance, and capacitance (RLC) circuit.

In one aspect, the one or more sensor modules comprise at least one of one or more temperature sensors, one or more ammeters, and one or more voltmeters.

In one aspect, the one or more circuits are electrically coupled to the one or more electric harnesses.

In one aspect, the first electrical parameter is a total resistance of the one or more electric harnesses.

In one aspect, the second electrical component comprises a predefined inductor.

In one aspect, the third electrical component is a predefined capacitor.

In one aspect, the one or more circuits comprise one or more predefined power supplies.

In one aspect, the inrush current flows through the one or more circuits when the third electrical component discharges and the one or more switches are closed.

In one aspect, the one or more electric harnesses are connected through a wire harness.

In one aspect, the threshold temperature comprises a temperature in a range of approximately −40° C. to 80° C.

In one aspect, the predefined inductor comprises an inductance in a range of approximately 1000 nH to 1000000 nH.

In one aspect, the predefined capacitor comprises a capacitance in a range of approximately 200 μF-200000 μF.

In one aspect, the one or more sensor modules are coupled to the one or more electric harnesses and the one or more circuits.

In one aspect, the first signal comprises one of an active signal and a passive signal.

In one aspect, the second signal comprises one of an active signal and a passive signal.

In one aspect, the one or more predefined power supplies comprises a voltage in a range of approximately 9V-16V, and/or 36V-52V.

In one aspect, the processor is operable to determine a third electrical parameter based on measurement of the inrush current, a first electrical component, and the second electrical component of the one or more circuits.

In one aspect, the first electrical component comprises a predefined resistor.

In one aspect, the predefined resistor comprises a resistance in a range of approximately 0.1 mOhm-200 mOhm.

In one aspect, the processor determines the integrity score of the one or more electric harnesses by comparing the first electrical parameter with a baseline value.

In one aspect, the processor stores the baseline value within a local memory.

In one aspect, the baseline value is used as a reference value for analysis of the integrity score.

In one aspect, the one or more electric harnesses are part of an vehicle.

In one aspect, the processor is operable to determine a state-of-charge of one of a battery pack and a power supply of the vehicle.

In one aspect, the processor is operable to monitor the state-of-charge of one of the battery pack and the power supply of the vehicle; and communicate the first signal to the one or more circuits to open the one or more switches within the one or more circuits when the state-of-charge of one of the battery pack and the power supply of the vehicle is greater than a threshold state-of-charge.

In one aspect, the processor is operable to determine the first electrical parameter at a plurality of time instances.

In one aspect, the processor is operable to determine the integrity score of the one or more electric harnesses based on a highest value among a plurality of values of the first electrical parameter determined at the plurality of time instances.

In one aspect, the one or more electric harnesses comprise at least one of one or more wires; one or more cables; one or more wire harnesses; one or more vehicle data busses; and one or more electric pathways.

In an aspect, a method is described. The method comprises: periodically monitoring, through one or more sensor modules, a temperature of one or more electric harnesses at a scheduled time intervals; communicating a first signal to one or more circuits to open one or more switches within the one or more circuits when the temperature of the one or more electric harnesses is less than a threshold temperature; enabling a third electrical component to discharge to a predefined voltage level; communicating a second signal to the one or more circuits to close the one or more switches causing an inrush current to flow through the one or more circuits; measuring, through the one or more sensor modules, the inrush current flowing through the one or more circuits; determining a first electrical parameter based on measurement of the inrush current, a second electrical component, and the third electrical component of the one or more circuits; and determining an integrity score of the one or more electric harnesses based on the first electrical parameter.

In one aspect, the first signal comprises one of an active signal and a passive signal.

In one aspect, the second signal comprises one of an active signal and a passive signal.

In one aspect, the method further comprises: determining a third electrical parameter based on the measurement of the inrush current, a first electrical component, and the second electrical component of the one or more circuits.

In one aspect, the method further comprises: determining the integrity score of the one or more electric harnesses by comparing the first electrical parameter with a baseline value.

In one aspect, the method further comprises: storing the baseline value within a local memory.

In one aspect, the baseline value is used as a reference value for comparing with measured values for analysis of the integrity score.

In one aspect, the one or more electric harnesses are part of an vehicle.

In one aspect, the method further comprises: determining a state-of-charge of one of a battery pack and a power supply of the vehicle.

In one aspect, the method further comprises: monitoring the state-of-charge of one of the battery pack and the power supply of the vehicle; and communicating the first signal to the one or more circuits to open the one or more switches within the one or more circuits when the state-of-charge of one of the battery pack and the power supply of the vehicle is greater than a threshold state-of-charge.

In one aspect, the method further comprises: determining the first electrical parameter at a plurality of time instances.

In one aspect, the method further comprises: determining the integrity score of the one or more electric harnesses based on a highest value among a plurality of values of the first electrical parameter determined at the plurality of time instances.

In an aspect, a non-transitory computer readable storage medium is described. The non-transitory computer readable storage medium comprises a sequence of instructions, which when executed by a processor causes: periodically monitoring, through one or more sensor modules, a temperature of one or more electric harnesses at a scheduled time intervals;

communicating a first signal to one or more circuits to open one or more switches within the one or more circuits when the temperature of the one or more electric harnesses is less than a threshold temperature; enabling a third electrical component to discharge to a predefined voltage level; communicating a second signal to the one or more circuits to close the one or more switches causing an inrush current to flow through the one or more circuits; measuring, through the one or more sensor modules, an inrush current flowing through the one or more circuits; determining a first electrical parameter based on measurement of the inrush current, a predefined second electrical component, and the predefined third electrical component of the one or more circuits; and determining an integrity score of the one or more electric harnesses based on the first electrical parameter.

In one aspect, the non-transitory computer readable medium, the first signal comprises one of an active signal and a passive signal.

In one aspect, the non-transitory computer readable medium, the second signal comprises one of an active signal and a passive signal.

In one aspect, the non-transitory computer readable medium, further causes: determining a third electrical parameter based on measurement of the inrush current, a first electrical component, and the second electrical component of the one or more circuits.

In one aspect, the non-transitory computer readable medium, further causes: determining the integrity score of the one or more electric harnesses by comparing the first electrical parameter with a baseline value.

In one aspect, the non-transitory computer readable medium, further causes: storing the baseline value within a local memory.

In one aspect, the baseline value is used as a reference value for analysis of the integrity score. In an aspect, the baseline value is measured using external oscilloscope.

In one aspect, the one or more electric harnesses are part of an vehicle.

In one aspect, the non-transitory computer readable medium, further causes: determining a state-of-charge of one of a battery pack and a power supply of the vehicle.

In one aspect, the non-transitory computer readable medium, further causes: monitoring the state-of-charge of one of the battery pack and the power supply of the vehicle; and communicating the first signal to the one or more circuits to open the one or more switches within the one or more circuits when the state-of-charge of one of the battery pack and the power supply of the vehicle is greater than a threshold state-of-charge.

In one aspect, the non-transitory computer readable medium, further causes: determining the first electrical parameter at a plurality of time instances. The time instances may be different points of time at which a certain temperature has been reached. The time instances may also be different points of time at which a certain number of tasks/operations have been completed. In one aspect, the time instances may be set by the processor based on the information received from the sensor module.

In one aspect, the non-transitory computer readable medium, further causes: determining the integrity score of the one or more electric harnesses based on a highest value among a plurality of values of the first electrical parameter determined at the plurality of time instances.

In one aspect, a system is described. The system comprises: one or more sensor modules; one or more electric harnesses; one or more circuits; and a processor. The processor storing instructions in non-transitory memory that, when executed, cause the processor to: determine one or more conditions to be met for conducting an integrity test on one of the one or more electric harnesses; maneuver a vehicle to a predefined location and rest until a predefined time period in accordance with the one or more conditions; and conduct the integrity test when a temperature of the one or more electric harnesses is less than a threshold temperature and a state-of-charge of a battery pack is greater than a threshold state-of-charge. In an aspect, the integrity test is performed in a range of approximately 20 days to 200 days. In another aspect, the integrity test is performed in a range of approximately 90 days to 180 days. In an aspect, the integrity test is performed when the vehicle is parked in a location with a known temperature for 4+ hours to let the temperature of the electric harnesses settle below the threshold temperature.

In one aspect, the processor is operable to: maneuver the vehicle to the predefined location comprising a spot that is covered from direct sunlight restricting the temperature from the sunlight.

In one aspect, the processor is operable to: maneuver the vehicle to the predefined location and rest until the predefined time period for a range of approximately four hours.

In one aspect, the processor is operable to: maneuver the vehicle to the predefined location comprising a spot that is covered with greeneries that reduces ambient temperature.

In one aspect, the processor is operable to: maneuver the vehicle to the predefined location comprising a spot that is closer to a location of the vehicle minimizing consumption of charge.

In one aspect, the processor is operable to: maneuver the vehicle to the predefined location comprising a charging station that charges the vehicle onboard energy storage device to a greater than the threshold state-of-charge and, optionally, operates a cooling fan that provides cooling to the vehicle below the threshold temperature.

In one aspect, the processor is operable to: operate at least one cooling fan of the vehicle to maintain the temperature of the one or more electric harnesses and the vehicle below the threshold temperature.

In an aspect, a method is described. The method comprises: determining one or more conditions to be met (e.g., temperatures arriving at or beyond the threshold temperature, battery arriving at or beyond the predetermined state of charge, and/or capacitor being charged or discharged to the predetermined level) for conducting an integrity test on one of one or more electric harnesses; maneuvering, by an autonomous driving kit or a driver, a vehicle to a predefined location and rest until a predefined time period in accordance with the one or more conditions; and conducting the integrity test when a temperature of the one or more electric harnesses is less than a threshold temperature and a state-of-charge of a battery pack is greater than a threshold state-of-charge.

In one aspect, the method further comprises: maneuvering the vehicle to the predefined location comprising a spot that is covered from direct sunlight restricting the temperature from the sunlight as determined by a global positioning system (GPS) or other suitable devices.

In one aspect, the method further comprises: maneuvering the vehicle to the predefined location and rest until the predefined time period for a range of approximately four hours.

In one aspect, the method further comprises: maneuvering the vehicle to the predefined location comprising a spot that is covered with greeneries that reduces ambient temperature.

In one aspect, the method further comprises: maneuvering the vehicle to the predefined location comprising a spot that is closer to a location of the vehicle minimizing consumption of charge.

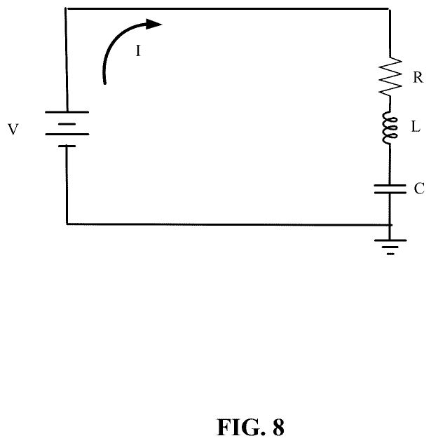

FIG. 8 is a block diagram illustrating a predefined circuit, according to one or more aspects. The predefined circuit described herein is an RLC circuit. The RLC circuit may be a series RLC circuit. The RLC circuit is adapted to determine an integrity level or integrity score of the one or more electric mediums without any external feedback. The RLC circuit comprises a resistor (R), an inductor (L), and a capacitor (C). The RLC circuit further comprises a power supply or a battery pack V to supply a voltage. The three variables V, L, and C may set to predefined values to solve the other variable R. The total resistance R is calculated similarly as below.

For example, in an RLC series circuit with a capacitance of 4.8 mF, an inductance of 0.520H, and a source voltage amplitude of 56.0V, operated at resonance frequency, the value of R for the resistor can be found by using the equation I-AV/R, where I is the current, ΔV is the voltage across the capacitor, and R is the resistor. At resonance, the impedance of the series C and L is zero, so the voltage of the source will only appear across R. Therefore, R can be calculated by dividing the source voltage by the current flowing through the circuit. The above example illustrates that the capacitance, the inductance, and the voltage values are set to predefined values. The temperature is also set to a threshold level. Other values may also be implemented according to various aspects of the present disclosure.

In another aspect, the natural variability of three variables V, L, and R is set to predefined values to solve the other variable capacitance C. The capacitance C may also be used to determine the integrity analysis. In order to achieve neutral thermal constants for R, L, C, and V, a significant temperature rest period may be required (e.g., 4+hr), during which the vehicle might be as close to completely off as possible. Batteries would also have to be held at a specific state of charge (SoC) (e.g., 100%).

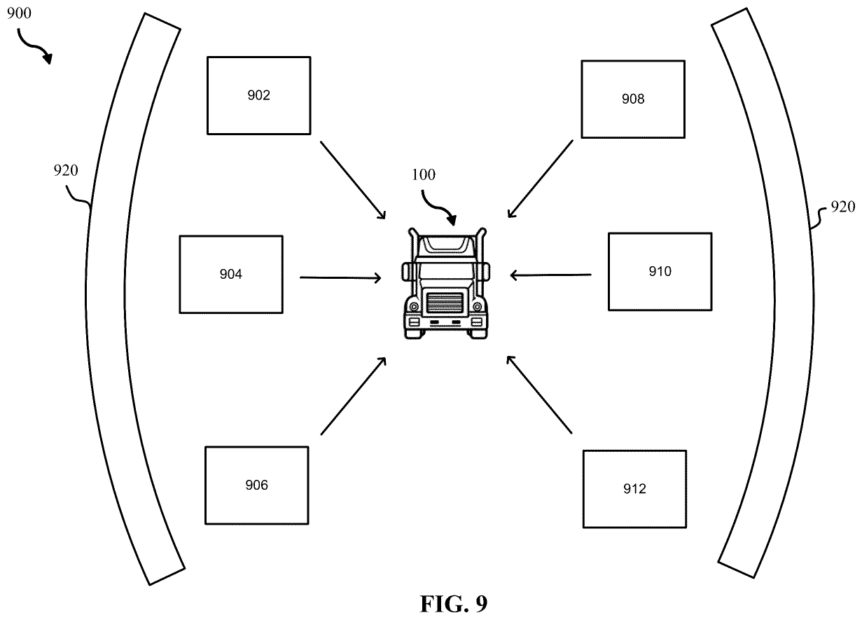

FIG. 9 is a block diagram of an example of au autonomous driving kit (ADK) 900 for operating the vehicle 100 according to aspects of the present disclosure. In an aspect, the ADK 900 may include a braking system 902 configured to apply mechanical forces to one or more components (e.g., brake pads) of the vehicle 100 to decrease the velocity of the vehicle 100. The ADK 900 may include a steering system 904 configured to apply mechanical forces to one or more components (e.g., steering column) of the vehicle 100 to control the direction of the vehicle 100. The ADK 900 may include an acceleration system 906 configured to apply mechanical forces to one or more components (e.g., gas pedal) of the vehicle to increase the velocity of the vehicle 100. The ADK 900 may include a sensor system 908 configured to detect a velocity of the vehicle 100, and/or one or more of objects, pedestrians, obstacles, terrain, environment, weather, and/or light intensity around with the vehicle 100. The ADK 900 may include a communication system 910 configured to communicate with other vehicles and/or remote systems. The ADK 900 may include a GPS system 912 configured to provide location data associated with the vehicle 100. The ADK 900 may include an artificial driver 920 configured to transmit control signals to and/or receive data signals from various components of the ADK 900 to operate the vehicle 100. The artificial driver 920 may optionally include a neural network configured to operate the vehicle 100 using artificial intelligence. The artificial driver 920 may include one or more programs and/or algorithms configured to properly operate the vehicle 100. Other components may also be included in the ADK 900 according to some aspects of the present disclosure.

The above disclosure may include definitions having various examples and/or forms of components that fall within the scope of a term and that may be used for implementation. The examples are not intended to be limiting.

Unless defined otherwise, all technical and scientific terms used herein have the same meaning as commonly understood by one with ordinary skill in the art to which this disclosure belongs.

As used herein, the articles “a” and “an” used herein refer to one or to more than one (i.e., to at least one) of the grammatical object of the article. By way of example, “an element” means one element or more than one element. Moreover, usage of articles “a” and “an” in the subject specification and annexed drawings construe to mean “one or more” unless specified otherwise or clear from context to mean a singular form.

As used herein, the term “example” does not limit the herein described subject matter. In addition, any aspect or design described herein as an “example” is not necessarily preferred or advantageous over other aspects or designs, nor does it preclude equivalent exemplary structures and techniques known to those of ordinary skill in the art.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the aspects described herein are, for example, capable of operation in sequences other than those illustrated or otherwise described herein.

Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

No element, act, or instruction used herein should be construed as critical or essential unless explicitly described as such. Furthermore, as used herein, the term “set” or “plurality” is intended to include items (e.g., related items, unrelated items, a combination of related items, and unrelated items, etc.), and may be used interchangeably with “one or more.” Further, the phrase “based on” is intended to mean “based, at least in part, on” unless explicitly stated otherwise.

As used herein, the terms “system,” “device,” “unit,” and/or “module” refer to a different component, component portion, or component of the various levels of the order. However, other expressions that achieve the same purpose may replace the terms.

The terms “couple,” “coupled,” “couples,” “coupling,” and the like should be broadly understood and refer to connecting two or more elements mechanically and/or otherwise. Two or more electrical elements may be electrically coupled together, but not be mechanically or otherwise coupled together. Coupling may be for any length of time, e.g., permanent or semi-permanent or only for an instant. “Electrical coupling” and the like should be broadly understood and include electrical coupling of all types. The absence of the word “removably,” “removable,” and the like near the word “coupled,” and the like does not mean that the coupling, etc. in question is or is not removable.

As used herein, the term “or” means an inclusive “or” rather than an exclusive “or.” That is, unless specified otherwise, or clear from context, “X employs A or B” means any of the natural inclusive permutations. That is, if X employs A; X employs B; or X employs both A and B, then “X employs A or B” is satisfied under any of the foregoing instances.

As defined herein, “approximately” can, in some aspects, mean within plus or minus ten percent of the stated value. In other aspects, “approximately” can mean within plus or minus five percent of the stated value. In further aspects, “approximately” can mean within plus or minus three percent of the stated value. In yet other aspects, “approximately” can mean within plus or minus one percent of the stated value.

As used herein, the term “component” broadly construes hardware, firmware, and/or a combination of hardware, firmware, and software.

Even though particular combinations of features are recited in the claims and/or disclosed in the specification, these combinations are not intended to limit the disclosure of possible implementations. Other implementations are within the scope of the claims. For example, the actions recited in the claims may be performed in a different order and still achieve desirable results. In fact, many of these features may be combined in ways not specifically recited in the claims and/or disclosed in the specification. Although each dependent claim may directly depend on only one claim, the disclosure of possible implementations includes each dependent claim in combination with every other claim in the claim set.

It will be appreciated that various implementations of the above-disclosed and other features and functions, or alternatives or varieties thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. An electrical system of a vehicle, comprising:
an electrical circuit having a harness and a capacitor;
one or more temperature sensors configured to measure one or more temperatures of the vehicle;
a power supply configured to provide electricity to the electrical circuit; and
a controller being configured to:
receive, from the one or more temperature sensors, one or more temperature measurements indicating the one or more temperatures;
transmit, in response to the one or more temperatures being below a threshold temperature, a first signal to activate a switch to charge or discharge the capacitor to a predetermined charge level;
transmit, in response to the capacitor being charged or discharged to a predetermined voltage level, a second signal to close the switch that causes an inrush current from the power supply to flow through the harness in the electrical circuit;
measure an electrical response associated with the harness based on the inrush current; and
determine a presence of a degradation associated with the harness based on the electrical response.

2. The electrical system of claim 1, further comprising an ammeter configured to measure a current through the harness;
wherein the controller is further configured to measure the electrical response by determining a resistance of the harness based on a voltage used to apply the inrush current and the measured current.

3. The electrical system of claim 2, wherein the controller is further configured to, prior to measuring the electrical response associated with the harness:
transmit a first initial signal to open the switch to discharge initial charges in the capacitor;
transmit, in response to the capacitor being charged or discharged to the predetermined voltage level, a second initial signal to close the switch that causes an initial inrush current to flow through the harness;
measure an initial electrical response associated with the harness based on the initial inrush current; and
determine a baseline parameter associated with the harness based on the initial electrical response.

4. The electrical system of claim 3, wherein:
the ammeter is further configured to measure an initial current through the harness; and
the controller is further configured to measure the initial electrical response by determining an initial resistance of the harness based on an initial voltage applied to apply the initial inrush current and the initial current.

5. The electrical system of claim 4, wherein the controller is further configured to determine the baseline parameter by identifying the initial resistance of the harness as the baseline parameter.

6. The electrical system of claim 5, wherein the controller is further configured to determine the degradation associated with the harness by:
determining a change in resistance based on a difference in the resistance and the initial resistance; and
determining the degradation based on the change in resistance.

7. The electrical system of claim 1, wherein the controller is further configured to:
compare the degradation to a threshold degradation;
determine, in response to comparing the degradation to the threshold degradation, the degradation being above the threshold degradation; and
perform one or more of:
transmitting, to a system of the vehicle, one or more signals to reduce an ability associated with the system, the system comprising the harness,
transmitting, to a system of the vehicle, one or more signals to monitor an ability associated with the system, the system comprising the harness, or
transmitting, to a system of the vehicle, one or more signals to terminate an ability associated with the system, the system comprising the harness.

8. The electrical system of claim 1, wherein the controller is further configured to, periodically:
transmit a first plurality of signals to open the switch to discharge the capacitor of the electrical circuit;
transmit, in response to the capacitor being charged or discharged to the predetermined voltage level, a second plurality of signals to close the switch that causes a plurality of inrush currents to flow through the harness in the electrical circuit;
measure a plurality of electrical responses associated with the harness each based on the plurality of inrush currents; and
determine one or more degradations associated with the harness based on the plurality of electrical responses.

9. A method of operating an electrical circuit in a vehicle, comprising:
measuring one or more temperatures of the vehicle;
transmitting, in response to the one or more temperatures being below a threshold temperature, a first signal to activate a switch to charge or discharge a capacitor of the electrical circuit to a predetermined charge level;
transmitting, in response to the capacitor being charged or discharged to a predetermined voltage level, a second signal to close the switch that causes an inrush current to flow through a harness in the electrical circuit;
measuring an electrical response associated with the harness based on the inrush current; and
determining a presence of a degradation associated with the harness based on the electrical response.

10. The method of claim 9, wherein measuring the electrical response comprises:
measuring a current through the harness; and
determining a resistance of the harness based a voltage used to apply the inrush current and the measured current.

11. The method of claim 10, further comprising, prior to measuring the electrical response associated with the harness:
transmitting a first initial signal to open the switch to discharge initial charges in the capacitor;
transmitting, in response to the capacitor being charged or discharged to the predetermined voltage level, a second initial signal to close the switch that causes an initial inrush current to flow toward the harness;
measuring an initial electrical response associated with the harness based on the initial inrush current; and
determining a baseline parameter associated with the harness based on the initial electrical response.

12. The method of claim 11, wherein measuring the initial electrical response comprises:
measuring an initial current through the harness; and
determining an initial resistance of the harness based on an initial voltage applied to apply the initial inrush current and the initial current.

13. The method of claim 12, wherein determining the baseline parameter comprises identifying the initial resistance of the harness as the baseline parameter.

14. The method of claim 13, wherein determining the degradation associated with the harness comprises:
determining a change in resistance based on a difference in the resistance and the initial resistance; and
determining the degradation based on the change in resistance.

15. The method of claim 9, further comprising:
comparing the degradation to a threshold degradation;
determining, in response to comparing the degradation to the threshold degradation, the degradation being above the threshold degradation; and
performing one or more of:
transmitting, to a system of the vehicle, one or more signals to reduce an ability associated with the system, the system comprising the harness,
transmitting, to a system of the vehicle, one or more signals to monitor an ability associated with the system, the system comprising the harness, or
transmitting, to a system of the vehicle, one or more signals to terminate an ability associated with the system, the system comprising the harness.

16. The method of claim 9, further comprising, periodically:
transmitting a first plurality of signals to open the switch to discharge the capacitor of the electrical circuit;
transmitting, in response to the capacitor being charged or discharged to the predetermined voltage level, a second plurality of signals to close the switch that causes a plurality of inrush currents to flow through the harness in the electrical circuit;
measuring a plurality of electrical responses associated with the harness each based on the plurality of inrush currents; and
determining one or more degradations associated with the harness based on the plurality of electrical responses.

17. A non-transitory computer readable medium comprising instructions that, when executed by one or more processors of in a vehicle, cause the one or more processors to:
measure one or more temperatures of the vehicle;
transmit, in response to the one or more temperatures being below a threshold temperature, a first signal to activate a switch to charge or discharge a capacitor of an electrical circuit to a predetermined charge level;
transmit, in response to the capacitor being charged or discharged to a predetermined voltage level, a second signal to close the switch that causes an inrush current to flow through a harness in the electrical circuit;
measure an electrical response associated with the harness based on the inrush current; and
determine a presence of a degradation associated with the harness based on the electrical response.

18. The non-transitory computer readable medium of claim 17, wherein the instructions for measuring the electrical response comprises instructions for:
measuring a current through the harness; and
determining a resistance of the harness based a voltage used to apply the inrush current and the measured current.

19. The non-transitory computer readable medium of claim 17, further comprising instructions for:
comparing the degradation to a threshold degradation;
determining, in response to comparing the degradation to the threshold degradation, the degradation being above the threshold degradation; and
performing one or more of:
transmitting, to a system of the vehicle, one or more signals to reduce an ability associated with the system, the system comprising the harness,
transmitting, to a system of the vehicle, one or more signals to monitor an ability associated with the system, the system comprising the harness, or
transmitting, to a system of the vehicle, one or more signals to terminate an ability associated with the system, the system comprising the harness.

20. The non-transitory computer readable medium of claim 17, further comprising instructions for, periodically:
transmitting a first plurality of signals to open the switch to discharge the capacitor of the electrical circuit;
transmitting, in response to the capacitor being charged or discharged to the predetermined voltage level, a second plurality of signals to close the switch that causes a plurality of inrush currents to flow through the harness in the electrical circuit;
measuring a plurality of electrical responses associated with the harness each based on the plurality of inrush currents; and
determining one or more degradations associated with the harness based on the plurality of electrical responses.
